(19) United States
(12) Patent Application Publication
(10) Pub. No.: US 2025/0287537 A1
(43) Pub. Date: Sep. 11, 2025

(54) THERMAL DIFFUSION DEVICE AND ELECTRONIC APPARATUS

(71) Applicant: Murata Manufacturing Co., Ltd., Nagaokakyo-shi (JP)

(72) Inventors: Masashi Morikami, Nagaokakyo-shi (JP); Tatsuhiro Numoto, Nagaokakyo-shi (JP)

(21) Appl. No.: 19/218,673

(22) Filed: May 27, 2025

Related U.S. Application Data
(63) Continuation of application No. PCT/JP2023/042516, filed on Nov. 28, 2023.

(30) Foreign Application Priority Data
Dec. 7, 2022 (JP) 2022-195644
Sep. 21, 2023 (JP) 2023-156426

(51) Int. Cl. H05K 7/20

(52) U.S. Cl. CPC H05K 7/20336

(57) ABSTRACT

A vapor chamber 1, which is an embodiment of a thermal diffusion device, includes: a housing 10 having a first inner surface 11a and a second inner surface 12a facing each other in a thickness direction Z, the housing 10 having an internal space; a working medium 20 enclosed in the internal space of the housing 10; and a wick 30 disposed in the internal space of the housing 10. The wick 30 has first through holes 61 having peripheries at which projections 65 toward the first inner surface 11a of the housing 10 in the thickness direction Z are provided. A space 70 is provided between tip end surfaces 65a of the projections 65 and the first inner surface 11a of the housing 10. A maximum length of the space 70 in the thickness direction Z is smaller than an inner diameter of each of the first through holes 61.

### CROSS REFERENCE TO RELATED APPLICATIONS

The present application is a continuation of International application No. PCT/JP2023/042516, filed Nov. 28, 2023, which claims priority to Japanese Patent Application No. 2022-195644, filed Dec. 7, 2022, and Japanese Patent Application No. 2023-156426, filed Sep. 21, 2023, the entire contents of each of which are incorporated herein by reference.

### TECHNICAL FIELD

The present disclosure relates to a thermal diffusion device and an electronic apparatus.

### BACKGROUND ART

In recent years, elements have been highly integrated and have been improved in performance, thus increasing the amount of heat generated. In addition, size reductions of products increase the heat generation densities thereof. Thus, measures to dissipate heat are important. This situation is particularly conspicuous in the field of mobile terminals such as smart phones and tablets. For example, a graphite sheet is often used as a member for countermeasures against heat. However, the amount of heat transported thereby is not sufficient. Thus, use of various members for countermeasures against heat has been examined. In particular, use of vapor chambers, which are planar heat pipes and are thermal diffusion devices capable of diffusing heat significantly effectively, has been examined.

Such a vapor chamber has a structure in which a working medium (also referred to as a working liquid) and a wick configured to transport the working medium by capillary force are enclosed in a housing. The working medium absorbs heat from a heat generation element such as an electronic component in an evaporation portion configured to absorb heat from the heat generation element, evaporates in the vapor chamber, moves in the vapor chamber, and is cooled to return to a liquid phase. The working medium that has returned to the liquid phase is moved to the evaporation portion closer to the heat generation element again by the capillary force of the wick and cools the heat generation element. By repeating this operation, the vapor chamber is capable of operating autonomously without external power and of diffusing heat two-dimensionally at high speed by using evaporation latent heat and condensation latent heat of the working medium.

Patent Document 1 discloses a vapor chamber including a housing, a working liquid, a microchannel, and a sheet wick. The housing includes an upper housing sheet and a lower housing sheet joined at respective outer edge portions thereof and facing each other and has an internal space. The working liquid is enclosed in the internal space. The microchannel is disposed in the part of the internal space in the lower housing sheet and forms a passage for the working liquid. The wick is disposed in the internal space of the housing so as to be in contact with the microchannel. The area where the wick and the microchannel are in contact with each other is 5 percent to 40 percent of the area of the internal space in plan view.
Patent Document 1: International Publication No. 2021/229961

### SUMMARY OF THE DISCLOSURE

FIG. 1 of Patent Document 1 illustrates, as an embodiment of the vapor chamber, the structure in which the wick is interposed between projections of the microchannel formed in the lower housing sheet and pillars formed on the upper housing sheet. In addition, Patent Document 1 explains that the wick has a plurality of microscopic holes formed by, for example, etching.

The capillary force of the wick is determined by the diameter size of the holes provided in the wick. However, there is a limit to reducing the diameter of the holes due to the constraints of processing methods such as etching.

The above problem is not limited to the vapor chamber and is a problem common to thermal diffusion devices capable of diffusing heat with a configuration similar to that of the vapor chamber.

The present disclosure is made to solve the above problem, and an object of the present disclosure is to provide a thermal diffusion device having a high capillary force. In addition, another object of the present disclosure is to provide an electronic apparatus including the thermal diffusion device.

A thermal diffusion device according to the present disclosure includes: a housing having a first inner surface and a second inner surface facing each other in a thickness direction, the housing having an internal space; a working medium enclosed in the internal space of the housing; and a wick disposed in the internal space of the housing. The wick has a first through hole having a periphery at which a projection toward the first inner surface of the housing in the thickness direction is provided. A space is provided between a tip end surface of the projection and the first inner surface of the housing. A maximum length of the space in the thickness direction is smaller than an inner diameter of the first through hole.

An electronic apparatus according to the present disclosure includes the thermal diffusion device according to the present disclosure.

According to the present disclosure, it is possible to provide a thermal diffusion device having a high capillary force. In addition, according to the present disclosure, it is possible to provide an electronic apparatus including the thermal diffusion device.

### BRIEF DESCRIPTION OF THE DRAWINGS

FIG. 1 is a schematic perspective view of an example of a thermal diffusion device according to a first embodiment of the present disclosure.

FIG. 2 is a schematic sectional view of an example of the thermal diffusion device according to the first embodiment of the present disclosure.

FIG. 3 is a schematic sectional view of examples of a housing and a wick that form the thermal diffusion device according to the first embodiment of the present disclosure.

FIG. 4 is a schematic plan view of an example of the wick illustrated in FIG. 3.

FIG. 5 is a schematic perspective view of an example of a projection provided at the periphery of a first through hole.

FIG. 6 is a schematic sectional view of a first modification example of a part represented by a in FIG. 3.

FIG. 7 is a schematic sectional view of a second modification example of the part represented by a in FIG. 3.

FIG. 8 is a schematic sectional view of a third modification example of the part represented by a in FIG. 3.

FIG. 9 is a schematic sectional view of a fourth modification example of the part represented by a in FIG. 3.

FIGS. 10A and 10B are schematic perspective views illustrating an example of a method for forming folded protrusions at a tip end surface of the projection.

FIG. 11 is a schematic sectional view of a fifth modification example of the part represented by a in FIG. 3.

FIG. 12 is a schematic sectional view of a sixth modification example of the part represented by a in FIG. 3.

FIG. 13 is a schematic sectional view of a seventh modification example of the part represented by a in FIG. 3.

FIG. 14 is a schematic sectional view of examples of a housing and a wick that form a thermal diffusion device according to a second embodiment of the present disclosure.

FIG. 15 is a schematic sectional view of a modification example of the shape of the projection toward a first inner surface of the housing.

### DESCRIPTION OF THE PREFERRED EMBODIMENTS

A thermal diffusion device according to the present disclosure will be described below.

However, the present disclosure is not limited to the following embodiments, and modifications can be applied thereto as appropriate without changing the gist of the present disclosure. Combinations of two or more different preferable configurations of the present disclosure described below are also included in the present disclosure.

In the thermal diffusion device according to the present disclosure, a wick has first through holes having peripheries at which projections toward a first inner surface of a housing in the thickness direction are provided. Thus, it is possible to form a liquid passage for a working medium between the projections adjacent to each other.

In addition, in the thermal diffusion device according to the present disclosure, a space is provided between tip end surfaces of the projections provided at the peripheries of the first through holes and the first inner surface of the housing such that the first through holes are not closed by the first inner surface of the housing. This space causes a capillary force. In addition, the maximum length of the space in the thickness direction (hereinafter also referred to as the height of the space) is smaller than the inner diameter of each of the first through holes, thus causing a higher capillary force.

As described in Patent Document 1, there is a limit to reducing the diameter of the holes of the wick due to processing methods. However, the structure in which the space is provided between the tip end surfaces of the projections and the first inner surface of the housing facilitates the control of the height of the space. Thus, it is possible to achieve an effect similar to the effect of reducing the diameter of the holes.

It is needless to say that the embodiments described below are examples, and configurations of different embodiments can be partially replaced or combined. From a second embodiment, points in common with a first embodiment are not described, and only different points are described. In particular, similar operational effects resulting from similar configurations are not mentioned in each embodiment.

In the following description, when the embodiments are not particularly distinguished from each other, it is simply referred to as “thermal diffusion device according to the present disclosure”.

In the following description, a vapor chamber is taken as an embodiment of the thermal diffusion device according to the present disclosure. The thermal diffusion device according to the present disclosure is also applicable to thermal diffusion devices such as a heat pipe.

Figures described below are schematic, and, for example, the size or the aspect ratio thereof may differ from that of an actual product. In the figures, the same reference signs are used for the same or corresponding portions. In addition, in the figures, the same elements have the same reference signs, and redundant descriptions thereof are omitted.

In the description, the terms representing the relationships between elements (such as “vertical”, “parallel”, and “orthogonal”) and the terms representing the shapes of the elements not only have strictly literal meanings but also have substantially equivalent meanings, for example, with a difference of about several percent.

### First Embodiment

In the thermal diffusion device according to the first embodiment of the present disclosure, in addition to the first through holes having the peripheries at which the projections toward the first inner surface of the housing in the thickness direction are provided, the wick has second through holes having peripheries at which no projections toward the first inner surface or a second inner surface of the housing in the thickness direction are provided.

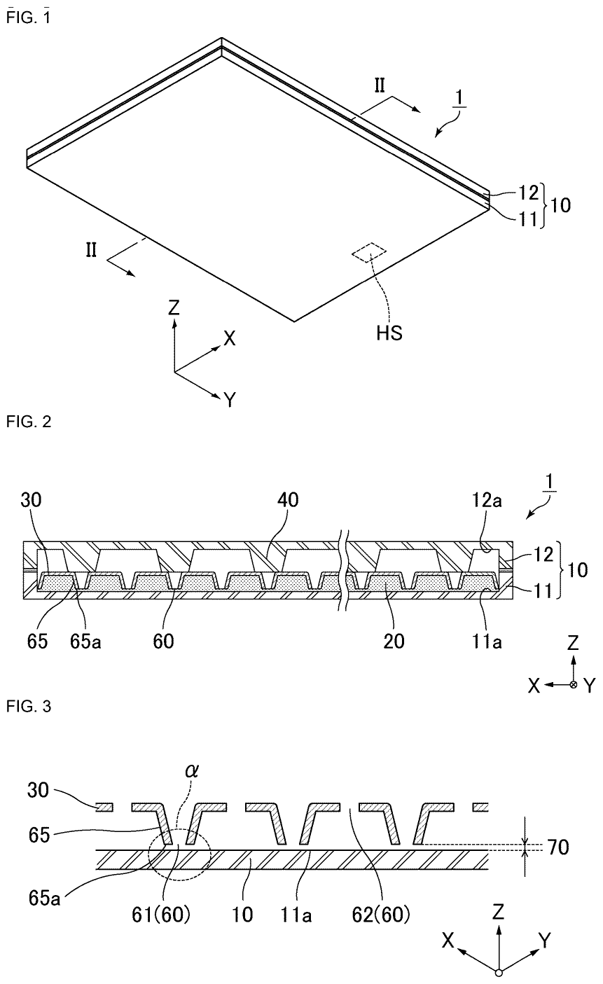

FIG. 1 is a schematic perspective view of an example of the thermal diffusion device according to the first embodiment of the present disclosure. FIG. 2 is a schematic sectional view of an example of the thermal diffusion device according to the first embodiment of the present disclosure. FIG. 2 is an example of a sectional view of the thermal diffusion device taken along line II-II in FIG. 1.

A vapor chamber (thermal diffusion device) 1 illustrated in FIGS. 1 and 2 includes a housing 10, which is hollow and is hermetically sealed. The housing 10 has a first inner surface 11a and a second inner surface 12a, which face each other in a thickness direction Z. The housing 10 has an internal space. The vapor chamber 1 further includes a working medium 20 enclosed in the internal space of the housing 10, and a wick 30 disposed in the internal space of the housing 10. The vapor chamber 1 may further include pillars 40 disposed in the internal space of the housing 10.

An evaporation portion configured to evaporate the enclosed working medium 20 is set in the housing 10. As illustrated in FIG. 1, a heat source HS, which is a heat generation element, is disposed on an outer surface of the housing 10. Examples of the heat source HS include electronic components of an electronic apparatus, such as a central processing unit (CPU). A part in the internal space of the housing 10 that is located in the vicinity of the heat source HS and that is configured to be heated by the heat source HS corresponds to the evaporation portion.

The vapor chamber 1 preferably has a planar shape as a whole. That is, the housing 10 preferably has a planar shape as a whole. Here, “planar shape” includes a plate-like shape and a sheet-like shape and means a shape in which the measurement in a width direction X (hereinafter referred to as the width) and the measurement in a length direction Y (hereinafter referred to as the length) are considerably larger than the measurement in the thickness direction Z (hereinafter referred to as the thickness or the height), for example, a shape in which the width and the length are 10 times or more, preferably 100 times or more, of the thickness.

The size of the vapor chamber 1, that is, the size of the housing 10 is not particularly limited. The width and the length of the vapor chamber 1 can be appropriately set according to its use. Each of the width and the length of the vapor chamber 1 is, for example, 5 mm to 500 mm, 20 mm to 300 mm, or 50 mm to 200 mm. The width and the length of the vapor chamber 1 may be equal to or different from each other.

The housing 10 is preferably formed by a first sheet 11 and a second sheet 12, which are joined at respective outer edge portions thereof and face each other.

When the housing 10 is formed by the first sheet 11 and the second sheet 12, the material forming the first sheet 11 and the second sheet 12 is not particularly limited as long as having characteristics, such as a thermal conductivity, a strength, elasticity, and flexibility, suitable for such a thermal diffusion device such as a vapor chamber. The material forming the first sheet 11 and the second sheet 12 is preferably a metal. Examples of such a metal include copper, nickel, aluminum, magnesium, titanium, iron, and alloys mainly composed of these metals. Particularly preferably, the material forming the first sheet 11 and the second sheet 12 is copper. The material forming the first sheet 11 may be the same as or different from the material forming the second sheet 12. Preferably, the material forming the first sheet 11 is the same as the material forming the second sheet 12.

When the housing 10 is formed by the first sheet 11 and the second sheet 12, the first sheet 11 and the second sheet 12 are joined at the respective outer edge portions thereof. The joining method is not particularly limited. Usable examples of such a joining method include laser welding, resistance welding, diffusion bonding, brazing, TIG welding (tungsten-inert gas welding), ultrasonic welding, and resin sealing. Preferably, it is possible to use laser welding, resistance welding, or brazing.

The thickness of the first sheet 11 and the thickness of the second sheet 12 are not particularly limited. Each of the thickness of the first sheet 11 and the thickness of the second sheet 12 is preferably 10 μm to 200 μm, more preferably 30 μm to 100 μm, even more preferably 40 μm to 60 μm. The thickness of the first sheet 11 and the thickness of the second sheet 12 may be equal to or different from each other. In addition, the thickness of each of the first sheet 11 and the second sheet 12 may be entirely uniform or partially thin.

The shape of the first sheet 11 and the shape of the second sheet 12 are not particularly limited. For example, each of the first sheet 11 and the second sheet 12 may be shaped such that the outer edge portion is thicker than the part thereof other than the outer edge portion.

The thickness of the entire vapor chamber 1 is not particularly limited and is preferably 50 μm to 500 μm.

The shape of the housing 10 in plan view when viewed in the thickness direction Z is not particularly limited. Examples of the shape of the housing 10 in plan view include a polygon such as a triangle or a rectangle, a circle, an ellipse, and shapes formed by combining these shapes. In addition, the shape of the housing 10 in plan view may be, for example, an L shape, a C shape (U shape), or a stepped shape. In addition, the housing 10 may have a through hole. The shape of the housing 10 in plan view may be a shape formed according to the use of a thermal diffusion device such as a vapor chamber, the shape of a part into which the thermal diffusion device is inserted, or other components located in the vicinity of the housing 10.

The working medium 20 is not particularly limited as long as being capable of changing between a gas phase and a liquid phase in the environment in the housing 10. Usable examples of the working medium 20 include water, alcohol, and alternative CFCs. For example, the working medium 20 is an aqueous compound, preferably water.

The wick 30 has a capillary structure capable of moving the working medium 20 by capillary force. The wick 30 preferably has a planar shape.

The material forming the wick 30 is not particularly limited and is preferably a metal. Examples of such a metal include copper, nickel, aluminum, magnesium, titanium, iron, and alloys mainly composed of these metals. Particularly preferably, the material forming the wick 30 is copper. The material forming the wick 30 may be the same as or different from the material forming the housing 10.

The size and the shape of the wick 30 are not particularly limited. For example, the wick 30 is preferably disposed continuously in the internal space of the housing 10. When viewed in the thickness direction Z, the wick 30 may be disposed in the entire internal space of the housing 10. When viewed in the thickness direction Z, the wick 30 may be disposed in part of the internal space of the housing 10.

The thickness of the wick 30 is not particularly limited and is, for example, 5 μm to 50 μm.

As illustrated in FIG. 2, the pillars 40 in contact with the second inner surface 12a may be disposed in the internal space of the housing 10. The disposition of the pillars 40 in the internal space of the housing 10 enables the housing 10 and the wick 30 to be supported.

The material forming the pillars 40 is not particularly limited. Examples of the material forming the pillars 40 include a resin, a metal, ceramic, and mixtures and laminates of these substances. In addition, as illustrated in FIG. 2, the pillars 40 may be integrally formed with the housing 10 and may be formed by, for example, subjecting the second inner surface 12a of the housing 10 to etching.

The shape of the pillars 40 is not particularly limited as long as the pillars 40 are shaped so as to be able to support the housing 10 and the wick 30. Examples of the shape of a section of the pillar 40 perpendicular to the height direction include a polygon such as a rectangle, a circle, and an ellipse.

As illustrated in FIG. 2, the pillar 40 may have a tapered shape in which the width of the pillar 40 narrows from the second inner surface 12a of the housing 10 toward the wick 30. Thus, it is possible to widen the part of a passage between the pillars 40 on the wick 30 side.

In the vapor chamber, each height of the pillars 40 may be equal or different. The height of the pillars 40 is, for example, 50 μm to 1000 μm.

The disposition of the pillars 40 is not particularly limited. The pillars 40 in a predetermined region are preferably evenly disposed, or more preferably all the pillars 40 are evenly disposed such that, for example, the center-to-center distance (pitch) of the pillars 40 adjacent to each other is uniform. The pillars 40 are evenly disposed, thus enabling the entire thermal diffusion device such as a vapor chamber to have a uniform strength. The center-to-center distance of the pillars 40 is, for example, 100 μm to 5000 μm.

In the section illustrated in FIG. 2, the width of the pillar 40 is not particularly limited as long as the pillar 40 has a strength sufficient to inhibit deformation of the housing 10. The equivalent circle diameter of a section perpendicular to the height direction of the end portion of the pillar 40 closer to the wick 30 is, for example, 100 μm to 2000 μm, preferably 300 μm to 1000 μm. An increase in the equivalent circle diameter of the pillar 40 enables deformation of the housing 10 to be further inhibited. On the other hand, a reduction in the equivalent circle diameter of the pillar 40 enables formation of a wider space for moving vapor of the working medium 20.

In the vapor chamber 1, the wick 30 has through holes 60 passing through the wick 30 in the thickness direction Z.

Capillary action enables the working medium 20 to move in the through holes 60. The shape of the through holes 60 is not particularly limited. Preferably, a section of the through hole 60 perpendicular to the thickness direction Z is a circle or an ellipse.

The disposition of the through holes 60 is not particularly limited. The through holes 60 in a predetermined region are preferably evenly disposed, or more preferably all the through holes 60 are evenly disposed such that, for example, the center-to-center distance (pitch) of the through holes 60 adjacent to each other is uniform.

The through holes 60 can be formed by, for example, punching metal foil forming the wick 30 in press working.

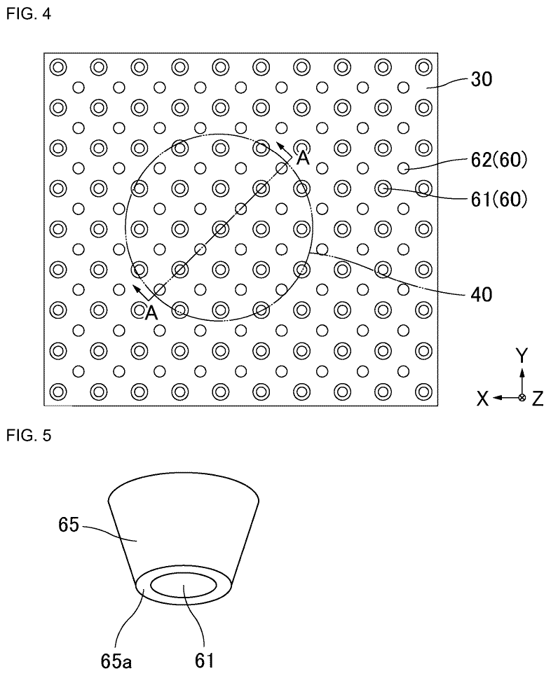

FIG. 3 is a schematic sectional view of examples of a housing and a wick that form the thermal diffusion device according to the first embodiment of the present disclosure. FIG. 4 is a schematic plan view of an example of the wick illustrated in FIG. 3. FIG. 3 illustrates a section of the wick taken along line A-A in FIG. 4.

In the example illustrated in FIGS. 3 and 4, the wick 30 has first through holes 61 and second through holes 62, which are the through holes 60.

As illustrated in FIG. 3, a projection 65 toward the first inner surface 11a of the housing 10 in the thickness direction Z is provided at the periphery of each first through hole 61.

On the other hand, no projection 65 toward the first inner surface 11a or the second inner surface 12a (see FIG. 2) of the housing 10 in the thickness direction Z is provided at the periphery of each second through hole 62.

The working medium 20 in a liquid phase is held between the projections 65 provided at the peripheries of the first through holes 61. Thus, it is possible to improve the heat transport performance of a thermal diffusion device such as a vapor chamber.

In addition, a space 70 is provided between tip end surfaces 65a of the projections 65 and the first inner surface 11a of the housing 10. The maximum length of the space 70 in the thickness direction Z (the height of the space 70) is smaller than the inner diameter of each of the first through holes 61. The space 70 causes a high capillary force.

The maximum length of the space 70 in the thickness direction Z may be, for example, 30 μm or less. On the other hand, the maximum length of the space 70 in the thickness direction Z may be, for example, 1 μm or more.

The inner diameter of each of the first through holes 61 may be, for example, 40 μm or less. On the other hand, the inner diameter of each of the first through holes 61 may be, for example, 5 μm or more.

The inner diameter of the first through hole 61 means the equivalent circle diameter of the first through hole 61 located in the tip end surface 65a of the projection 65. The inner diameter of the first through hole 61 is preferably smaller than the equivalent circle diameter of a section perpendicular to the height direction of the end portion of the pillar 40 closer to the wick 30.

The center-to-center distance of the first through holes 61 is, for example, 60 μm to 800 μm. The center-to-center distance of the first through holes 61 is preferably smaller than the center-to-center distance of the pillars 40.

The inner diameter of each of the second through holes 62 is, for example, 100 μm or less. The inner diameter of the second through hole 62 may be equal to the inner diameter of the first through hole 61, may be larger than the inner diameter of the first through hole 61, or may be smaller than the inner diameter of the first through hole 61. When the second through holes 62 have different inner diameters when viewed in the thickness direction Z, the inner diameter of the smallest one of the second through holes 62 is defined as the inner diameter of the second through hole 62.

The center-to-center distance of the second through holes 62 is, for example, 3 μm to 150 μm. The center-to-center distance of the second through holes 62 may be equal to the center-to-center distance of the first through holes 61, may be larger than the center-to-center distance of the first through holes 61, or may be smaller than the center-to-center distance of the first through holes 61.

The disposition of the projections 65 is not particularly limited. The projections 65 in a predetermined region are preferably evenly disposed, or more preferably all the projections 65 are evenly disposed such that, for example, the center-to-center distance (pitch) of the projections 65 adjacent to each other is uniform.

The height of the projection 65 is, for example, 10 μm to 100 μm. The height of the projection 65 is preferably smaller than the height of the pillar 40.

The size of the projection 65 is not particularly limited. For example, the height of the projection 65 may be larger than the inner diameter of the first through hole 61, may be smaller than the inner diameter of the first through hole 61, or may be equal to the inner diameter of the first through hole 61.

The projections 65 can be formed by, for example, punching metal foil forming the wick 30 in press working. In this case, the projections 65 may be formed simultaneously with the through holes 60 such as the first through holes 61 or may be formed separately from the through holes 60 such as the first through holes 61. In the punching process in press working, for example, the shape of the projections 65 can be adjusted by appropriately adjusting the punching depth or the like. The punching depth means, for example, the depth of a punch pushed in a punching direction when the punching process is performed by using the punch.

The thickness of metal foil yet to be subjected to working such as press working is preferably uniform. However, parts of the metal foil subjected to press working may be thin. Thus, in the example illustrated in FIG. 3, preferably, the thickness of the projections 65 is equal to the thickness of the part of the wick 30 other than the projections 65 or is smaller than the thickness of the part of the wick 30 other than the projections 65.

FIG. 5 is a schematic perspective view of an example of a projection provided at the periphery of a first through hole.

In the example illustrated in FIG. 5, the tip end surface 65a of the projection 65 has a flat structure.

The projection 65 may be provided only at part of the periphery of the first through hole 61. However, as illustrated in FIG. 5, the projection 65 is preferably provided at the entire periphery of the first through hole 61.

Preferably, the projections 65 are not joined to the first inner surface 11a of the housing 10. As long as the space 70 is provided between the tip end surfaces 65a of the projections 65 and the first inner surface 11a of the housing 10, part of the tip end surface 65a of the projection 65 may be in contact with the first inner surface 11a of the housing 10.

When a plurality of the projections 65 are provided to the wick 30, the shape of the space 70 may be a uniform shape, a shape formed by combining two or more shapes, or an entirely randomly varying shape. In addition, the projections 65 may be included such that no space 70 is provided between the tip end surfaces 65a of the projections 65 and the first inner surface 11a of the housing 10.

The tip end surface 65a of the projection 65 may have an uneven structure. In this case, the tip end surface 65a of the projection 65 having the uneven structure may enable the space 70 to be provided between the tip end surfaces 65a of the projections 65 and the first inner surface 11a of the housing 10.

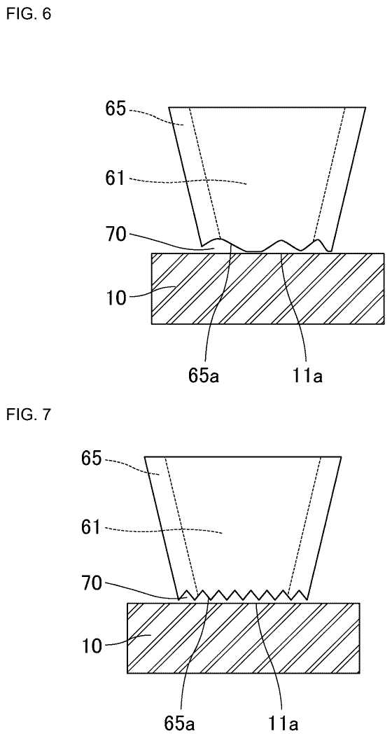

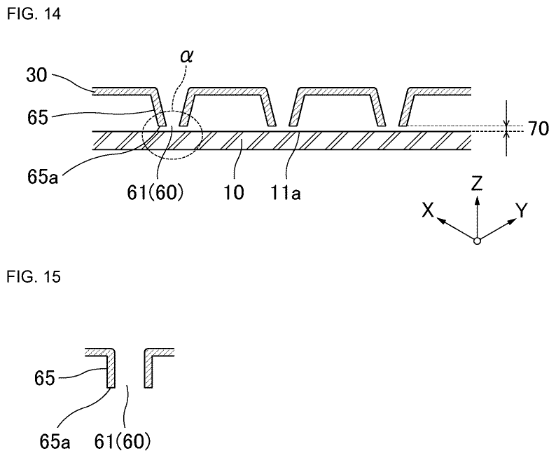

FIG. 6 is a schematic sectional view of a first modification example of a part represented by a in FIG. 3. In FIG. 3, a represents the part between the tip end surface 65a of the projection 65 and the first inner surface 11a of the housing 10. The same applies to FIG. 14 to be described later.

In the example illustrated in FIG. 6, the tip end surface 65a of the projection 65 has a curvilinear wave sectional shape.

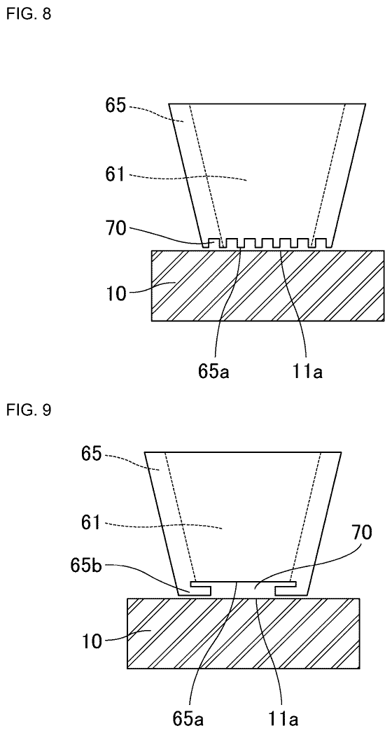

FIG. 7 is a schematic sectional view of a second modification example of the part represented by a in FIG. 3.

In the example illustrated in FIG. 7, the tip end surface 65a of the projection 65 has a triangular wave sectional shape.

FIG. 8 is a schematic sectional view of a third modification example of the part represented by a in FIG. 3.

In the example illustrated in FIG. 8, the tip end surface 65a of the projection 65 has a rectangular wave sectional shape.

FIG. 9 is a schematic sectional view of a fourth modification example of the part represented by a in FIG. 3.

In the example illustrated in FIG. 9, folded protrusions 65b each protruding toward the inside of the first through hole 61 in a radial direction are provided to the tip end surface 65a of the projection 65.

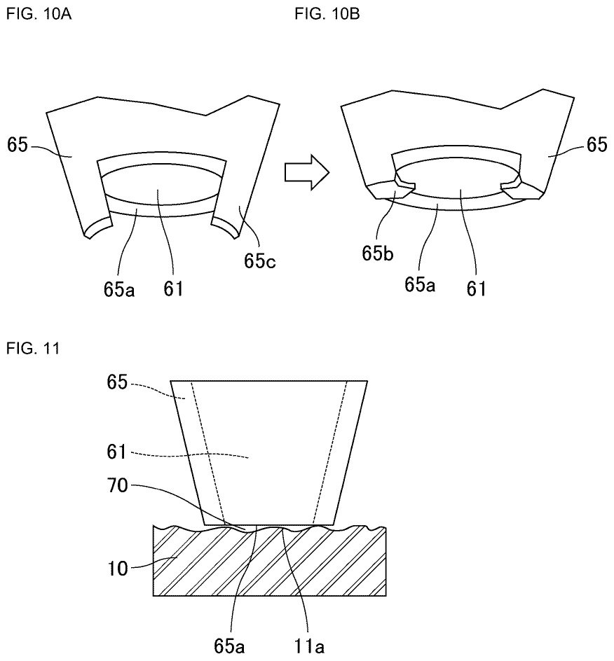

FIGS. 10A and 10B are schematic perspective views illustrating an example of a method for forming folded protrusions at the tip end surface of the projection.

For example, when the projections 65 are formed by punching in working such as press working, as illustrated in FIG. 10A, plate protrusions 65c are formed on the tip end surface 65a of the projection 65 as burrs formed during the working. Thereafter, the projections 65 are flattened by working such as roll pressing. Thus, as illustrated in FIG. 10B, the plate protrusions 65c are bent to form the folded protrusions 65b.

Alternatively, the first inner surface 11a of the housing 10 may have an uneven structure, thus enabling the space 70 to be provided between the tip end surfaces 65a of the projections 65 and the first inner surface 11a of the housing 10. In this case, the tip end surface 65a of the projection 65 may have a flat structure or an uneven structure.

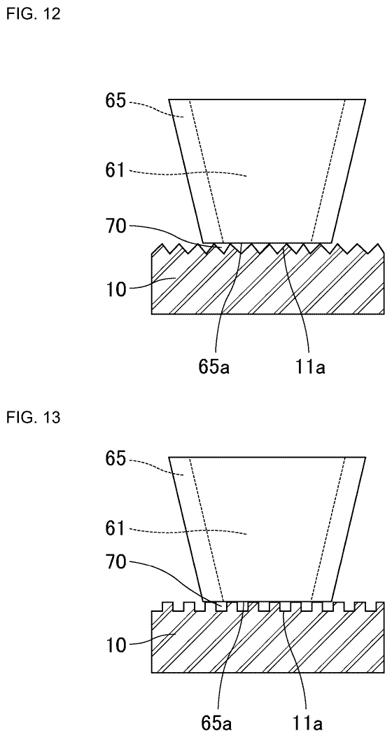

FIG. 11 is a schematic sectional view of a fifth modification example of the part represented by a in FIG. 3.

In the example illustrated in FIG. 11, the first inner surface 11a of the housing 10 has a curvilinear wave sectional shape.

FIG. 12 is a schematic sectional view of a sixth modification example of the part represented by a in FIG. 3.

In the example illustrated in FIG. 12, the first inner surface 11a of the housing 10 has a triangular wave sectional shape.

FIG. 13 is a schematic sectional view of a seventh modification example of the part represented by a in FIG. 3.

In the example illustrated in FIG. 13, the first inner surface 11a of the housing 10 has a rectangular wave sectional shape.

Any of the structures of the tip end surface 65a of the projection 65 illustrated in FIGS. 6 to 9 may be combined with any of the structures of the first inner surface 11a of the housing 10 illustrated in FIGS. 11 to 13.

### Second Embodiment

In the thermal diffusion device according to the second embodiment of the present disclosure, the wick only has the first through holes having peripheries at which the projections toward the first inner surface of the housing in the thickness direction are provided.

FIG. 14 is a schematic sectional view of examples of the housing and the wick that form the thermal diffusion device according to the second embodiment of the present disclosure.

In the example illustrated in FIG. 14, the wick 30 only has the first through holes 61, which are the through holes 60. On the other hand, the wick 30 has no second through holes 62 (see FIG. 3), which are the through holes 60.

As illustrated in FIG. 14, the projections 65 toward the first inner surface 11a of the housing 10 in the thickness direction Z are provided at the peripheries of the first through holes 61.

In addition, the space 70 is provided between the tip end surfaces 65a of the projections 65 and the first inner surface 11a of the housing 10. The maximum length of the space 70 in the thickness direction Z (the height of the space 70) is smaller than the inner diameter of the first through hole 61.

In addition, the structure of a part represented by a in FIG. 14 is similar to the structure described in the first embodiment.

### OTHER EMBODIMENTS

The thermal diffusion device according to the present disclosure is not limited to the above embodiments. Various applications and modifications can be made to, for example, the configuration and the manufacturing conditions of the thermal diffusion device within the scope of the present disclosure.

For example, the shape of the projections 65 toward the first inner surface 11a of the housing 10 in the thickness direction Z is not particularly limited.

FIG. 15 is a schematic sectional view of a modification example of the shape of the projection toward the first inner surface of the housing.

As illustrated in FIG. 15, the distance across an outer wall of the projection 65 may be uniform toward the tip end surface 65a of the projection 65.

Alternatively, as illustrated in, for example, FIG. 3, the distance across the outer wall of the projection 65 may be reduced toward the tip end surface 65a of the projection 65. In this case, the projection 65 may be shaped so as to project toward the first inner surface 11a (lower side in FIG. 3) or the second inner surface 12a (upper side in FIG. 3).

In addition, the distance across the outer wall of the projection 65 may be increased toward the tip end surface 65a of the projection 65. In this case, the projection 65 may be shaped so as to project toward the first inner surface 11a or the second inner surface 12a.

When the wick 30 has a plurality of the first through holes 61, the space 70 having a height (the maximum length in the thickness direction Z) larger than the inner diameter of the first through hole 61 may be provided between the tip end surfaces 65a of the projections 65 and the first inner surface 11a of the housing 10.

When the wick 30 has a plurality of the through holes 60, the first through holes 61 are included in the through holes 60, and the second through holes 62 may be included in the through holes 60 or do not have to be included in the through holes 60.

In the thermal diffusion device according to the present disclosure, the housing may include one or a plurality of evaporation portions. That is, one or a plurality of heat sources may be disposed on the outer wall surface of the housing.

In the thermal diffusion device according to the present disclosure, when the housing is formed by the first sheet and the second sheet, the first sheet and the second sheet may overlap such that end portions thereof coincide or do not coincide with each other.

In the thermal diffusion device according to the present disclosure, when the housing is formed by the first sheet and the second sheet, the material forming the first sheet and the material forming the second sheet may be different from each other. For example, use of a material having a high strength for the first sheet enables the stress applied to the housing to be dispersed. In addition, use of different materials for the respective sheets enables one of the sheets to have one function and the other of the sheets to have another function. Such functions are not particularly limited. Examples of such functions include a thermal conduction function and an electromagnetic shielding function.

The thermal diffusion device according to the present disclosure can be mounted in an electronic apparatus to dissipate heat. Thus, the present disclosure also includes an electronic apparatus including the thermal diffusion device according to the present disclosure. Examples of the electronic apparatus according to the present disclosure include a smart phone, a tablet terminal, a notebook computer, a game device, and a wearable device. As described above, the thermal diffusion device according to the present disclosure is capable of operating autonomously without external power and of diffusing heat two-dimensionally at high speed by using evaporation latent heat and condensation latent heat of a working medium. Thus, the electronic apparatus including the thermal diffusion device according to the present disclosure is capable of effectively dissipating heat in a limited space in the electronic apparatus.

The description discloses the following contents.

<1> A thermal diffusion device comprising: a housing having a first inner surface and a second inner surface facing each other in a thickness direction, the housing having an internal space; a working medium enclosed in the internal space of the housing; and a wick disposed in the internal space of the housing, wherein the wick has a first through hole having a periphery at which a projection toward the first inner surface of the housing in the thickness direction is provided, a space is provided between a tip end surface of the projection and the first inner surface of the housing, and a maximum length of the space in the thickness direction is smaller than an inner diameter of the first through hole.

<2> The thermal diffusion device according to <1>, wherein the tip end surface of the projection has an uneven structure to provide the space between the tip end surface of the projection and the first inner surface of the housing.

<3> The thermal diffusion device according to <1> or <2>, wherein the first inner surface of the housing has an uneven structure to provide the space between the tip end surface of the projection and the first inner surface of the housing.

<4> The thermal diffusion device according to any one of <1> to <3>, wherein the wick further has a second through hole having a periphery at which no projection toward the first inner surface or the second inner surface of the housing in the thickness direction is provided.

<5> The thermal diffusion device according to any one of <1> to <4>, wherein the maximum length of the space in the thickness direction is 30 μm or less.

<6> The thermal diffusion device according to any one of <1> to <5>, wherein the inner diameter of the first through hole is 40 μm or less.

<7> The thermal diffusion device according to any one of <1> to <6>, wherein the projection is not joined to the first inner surface of the housing.

<8> The thermal diffusion device according to any one of <1> to <7>, wherein a distance across an outer wall of the projection is reduced toward the tip end surface of the projection.

<9> The thermal diffusion device according to any one of <1> to <7>, wherein a distance across an outer wall of the projection is uniform toward the tip end surface of the projection.

<10> An electronic apparatus comprising the thermal diffusion device according to any one of <1> to <9>.

The thermal diffusion device according to the present disclosure can be used for various purposes in the field of, for example, portable information terminals. For example, the thermal diffusion device according to the present disclosure can be used to reduce the temperature of a heat source such as a CPU and to extend the operating time of an electronic apparatus and can be used for smart phones, tablet terminals, notebook computers, and the like.

### REFERENCE SIGNS LIST

1 vapor chamber (thermal diffusion device)
10 housing
11 first sheet
11a first inner surface
12 second sheet
12a second inner surface
20 working medium
30 wick
40 pillar
60 through hole
61 first through hole
62 second through hole
65 projection
65a tip end surface
65b folded protrusion
65c plate protrusion
70 space
HS heat source
X width direction
Y length direction
Z thickness direction

1. A thermal diffusion device comprising:
a housing having a first inner surface and a second inner surface facing each other in a thickness direction and defining an internal space;
a working medium enclosed in the internal space of the housing; and
a wick in the internal space of the housing, wherein
the wick has a first through hole having a first periphery and a projection at the first periphery of the through hole, the projection extending toward the first inner surface of the housing in the thickness direction so as to define a space between a tip end surface of the projection and the first inner surface of the housing, and
a maximum length of the space in the thickness direction is smaller than an inner diameter of the first through hole.

2. The thermal diffusion device according to claim 1, wherein the tip end surface of the projection has an uneven structure.

3. The thermal diffusion device according to claim 1, wherein the tip end surface of the projection has a flat structure.

4. The thermal diffusion device according to claim 1, wherein the first inner surface of the housing has an uneven structure.

5. The thermal diffusion device according to claim 1, wherein the wick further has a second through hole having a second periphery.

6. The thermal diffusion device according to claim 5, wherein the second periphery does not have a projection extending toward the first inner surface or the second inner surface of the housing in the thickness direction.

7. The thermal diffusion device according to claim 5, wherein an inner diameter of the second through hole is 100 μm or less.

8. The thermal diffusion device according to claim 1, wherein the maximum length of the space in the thickness direction is 30 μm or less.

9. The thermal diffusion device according to claim 1, wherein the maximum length of the space in the thickness direction is 1 μm to 30 μm.

10. The thermal diffusion device according to claim 1, wherein the inner diameter of the first through hole is 40 μm or less.

11. The thermal diffusion device according to claim 1, wherein the inner diameter of the first through hole is 5 μm to 40 μm.

12. The thermal diffusion device according to claim 1, wherein the projection is not joined to the first inner surface of the housing.

13. The thermal diffusion device according to claim 1, wherein a distance across an outer wall of the projection reduces in a direction toward the tip end surface of the projection.

14. The thermal diffusion device according to claim 1, wherein a distance across an outer wall of the projection is uniform in a direction toward the tip end surface of the projection.

15. The thermal diffusion device according to claim 1, wherein the thermal diffusion device includes a plurality of the first through holes and a center-to-center distance of adjacent first through holes of the plurality of first through holes is 60 μm to 800 μm.

16. The thermal diffusion device according to claim 15, further comprising a plurality of pillars extending in the thickness direction from the second inner surface, and wherein the center-to-center distance of the adjacent first through holes is smaller than a center-to-center distance of adjacent pillars of the plurality of pillars.

17. The thermal diffusion device according to claim 15, wherein the thermal diffusion device includes a plurality of second through holes and a center-to-center distance of adjacent second through holes of the plurality of second through holes is 3 μm to 150 μm.

18. The thermal diffusion device according to claim 1, wherein a height of the projection in the thickness direction is 10 μm to 100 μm.

19. An electronic apparatus comprising the thermal diffusion device according to claim 1.
